(19) United States
(12) Patent Application Publication
(10) Pub. No.: US 2006/0072287 A1
(43) Pub. Date: Apr. 6, 2006

(54) Portable computer system with rechargeable keyboard

(75) Inventors: Wah Yiu Kwong, Beaverton, OR (US); Wayne L. Proefrock, Hillsboro, OR (US)

Correspondence Address: INTEL CORPORATION, P.O. BOX 5326, SANTA CLARA, CA, 95056-5326, US

(73) Assignee: Intel Corporation

(21) Appl. No.: 10/956,944

(22) Filed: Sep. 30, 2004

(51) Int. Cl. H05K 5/00

(52) U.S. Cl. 361/683

(57) ABSTRACT

A computer system having a display housing and detachable a base housing. The base housing may include a keyboard that can communicate with the display housing via a wired interface or a wireless interface. The keyboard may also include a rechargeable battery. When the keyboard communicates with the display housing using the wired interface, a controller within the keyboard may cause the battery to be charged using a power signal available via the wired interface.

### COPYRIGHT NOTICE

Contained herein is material that is subject to copyright protection. The copyright owner has no objection to the facsimile reproduction of the patent disclosure by any person as it appears in the Patent and Trademark Office patent files or records, but otherwise reserves all rights to the copyright whatsoever.

### FIELD OF THE INVENTION

The present invention generally relates to the field of portable computer systems and more particularly related to computer systems that include detachable devices.

### BACKGROUND

Laptop computers, also referred to as notebook computers, are normally lightweight, battery-powered or AC-powered computer system. A laptop computer can be transported and used by a user in different environments including, for example, on an airplane, in a library, at a coffee shop, etc. Except for tablet and convertible computer systems, a laptop computer generally has a clam-shell form factor which includes a display section and a base section coupled to one another using a hinge mechanism.

The display section typically includes a display screen, and the base section typically includes a keyboard and other electronic components (e.g., processor, memory, buses, storage drives, a battery, etc.). In some laptop computer design, the processor and other electronic components may be in same housing as the display section, while the base section may include only the keyboard. The laptop computer may be closed by folding the display section on top of the base section.

A latching mechanism may be used to engage and lock the display section with the base section. The latching mechanism may also be used to disengage the display section from the base section. When the base section includes only the keyboard, disengaging the base section may not disable operation of the keyboard when the keyboard is also adapted to function as a wireless keyboard.

### BRIEF DESCRIPTION OF THE DRAWINGS

The invention is illustrated by way of example and not limitation in the figures of the accompanying drawings, in which like references indicate similar or identical elements, and in which:

FIG. 1 illustrates one example of a computer system having a display housing and a detachable base housing, in accordance with one embodiment.

FIG. 2 illustrates one example of components in a computer system having a detachable base housing, in accordance with one embodiment.

FIG. 3 is an example block diagram that illustrates a USB interface, in accordance with one embodiment.

FIG. 4 is a flow diagram illustrating one example of a process that may be performed by the connection controller, in accordance with one embodiment.

### DETAILED DESCRIPTION

For one embodiment, a computer system having a detachable keyboard is disclosed. In the following detailed description of the present invention numerous specific details are set forth in order to provide a thorough understanding of the present invention. However, it will be apparent to one skilled in the art that the present invention may be practiced without these specific details. In other instances, well-known structures and devices are shown in block diagram form, rather than in detail, in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Overview

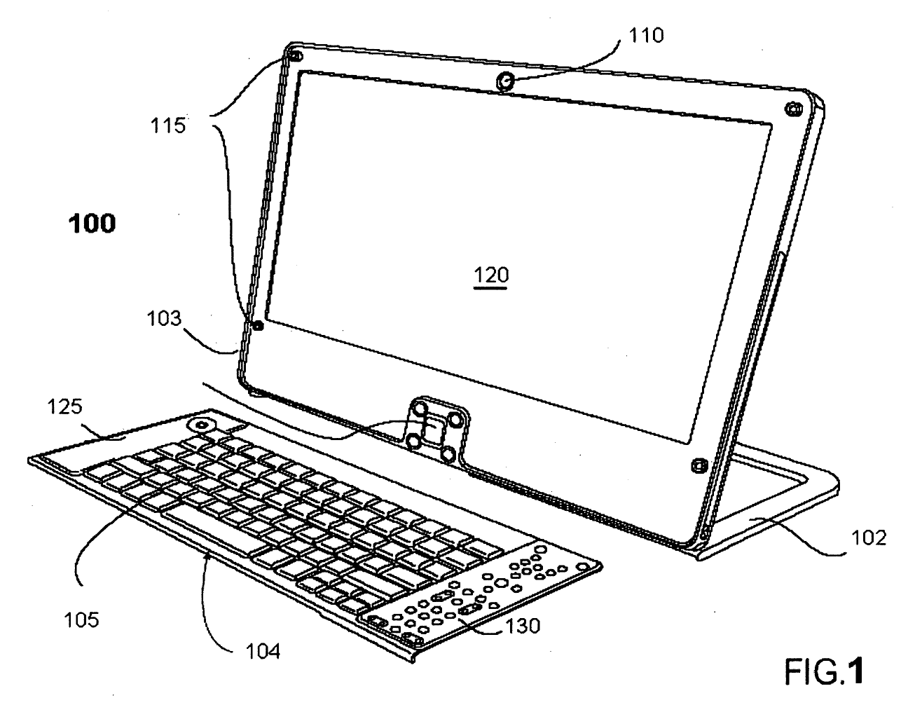

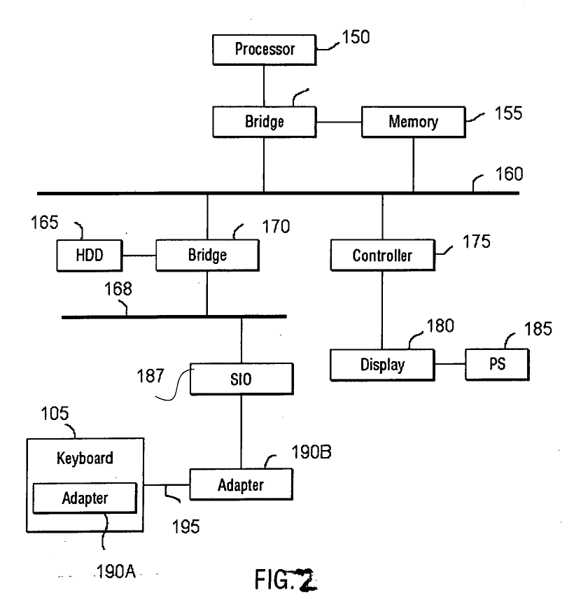

FIG. 1 illustrates one example of a computer system having a display housing and a detachable base housing, in accordance with one embodiment. Computer system 100 may include display housing 103 which may be rectangular and flat. The display housing 103 may include many electronic components, circuit boards and the like. For example, the display housing 103 may include a processor 150, communication adapter 190B, memory 155, bridges 152, 170, storage devices 165 (e.g., hard disk drive or HDD), bus 160, 168, display controller 175, display 180, I/O controller 187 (e.g. serial I/O controller), etc., as illustrated in FIG. 2. The I/O controller 187 may receive input from a keyboard 105 through keyboard connection 195. As will be discussed in more detail, the keyboard connection 195 may be wired or wireless.

The display housing 103 may be in an upright position supported by a stand 102 when the computer system 100 is in its normal operation mode. The display housing 103 may lie flat on its back side or its front side when the computer system 100 is not in its normal operation mode. Although the computer system 100 may not look like a typical desktop computer, it is envisioned that the computer system 100 may include features and may deliver performance close to or similar to a typical desktop computer. It is also envisioned that that the computer system 100 may occasionally be moved from place to place (i.e., portable) and that it may draw power from an alternating current (AC) power source or a direct current (DC) power source.

The computer system 100 may include base housing 104 which may be detachable. The base housing 104 may be a keyboard itself, or it may be a keyboard tray containing the keyboard 105. The base housing 104 may also include other devices (e.g., handset 125, remote control 130, etc.) that may be used with the computer system 100. For one embodiment, the base housing 104 may be engaged to or disengaged from the display housing 103 using a locking, attachment or hinge mechanism (not shown).

Keyboard with Wireless and Wired Capability

For one embodiment, when the base housing 104 is detached from the display housing 103, the keyboard 105 may communicate with the display housing 103 including the processor 150 using wireless communication. This may be accomplished using any one of a variety of techniques including, for example, an infrared communication link or a radio frequency communication link, etc. The keyboard 105 may include a wireless interface that supports wireless communication. For example, the wireless interface may be coupled to or included in the communication adapter 190A in the keyboard 105, as illustrated in FIG. 2. This wireless interface may enable the keyboard 105 to transmit signals (e.g., keystroke information, etc.) to a receiver in the communication adapter 190B in the display housing 103. Of course, the communication adapter 190B may also include or be coupled to another wireless interface to carry on the communications with the communication adapter 190A.

For one embodiment, the communication adapters 190A and 190B may be configured to support infrared red (IR) communications or radio frequency (RF) communications, which allow communications without a physical wired connection. When the communication adapters 190A and 190B support IR, they may be implemented in accordance with the Infrared Data Association (IrDA) standards and specifications (such as the Serial Infrared Link Access protocol Version 1.0, Jun. 23, 1994 which may be found at {www.irda.org}). When the communication adapters 190A and 190B support radio links, they may be implemented using the Bluetooth radio link, which is a short-range, cable replacement, radio technology. The Bluetooth radio communications is known to one skilled in the art.

For one embodiment, the communication adapter 190A in the keyboard 105 may include a wired interface to communicate with the display housing 103 including the processor 150. The wired interface enables the keyboard connection 195 to be a physical wired connection that connects the keyboard 105 and the base housing 104 to the display housing 103. For one embodiment, the wired interface is a Universal Serial Bus (USB) interface, and the keyboard connection 195 is a USB cable. Having a wired interface may be convenient in situations when the wireless interface may not be practical. For example, the wireless interface may not be used when the DC power supply is drained, when there is a lot of interference, when there is a non-support Operating System (OS) environment, during system boot and post, etc. Using a wired interface may be advantageous when a user prefers a more secured environment. One skilled in the art may recognize that other wired interface such as, for example, a PS/2 keyboard interface, etc., may also be used.

Power to the Keyboard

Typically, when the computer system 100 is a laptop or a portable computer system, power to the keyboard may be provided when the computer system 100 is docked through a fixed electrical connection available via a docking station or similar devices. The docking station may be connected to an AC power supply.

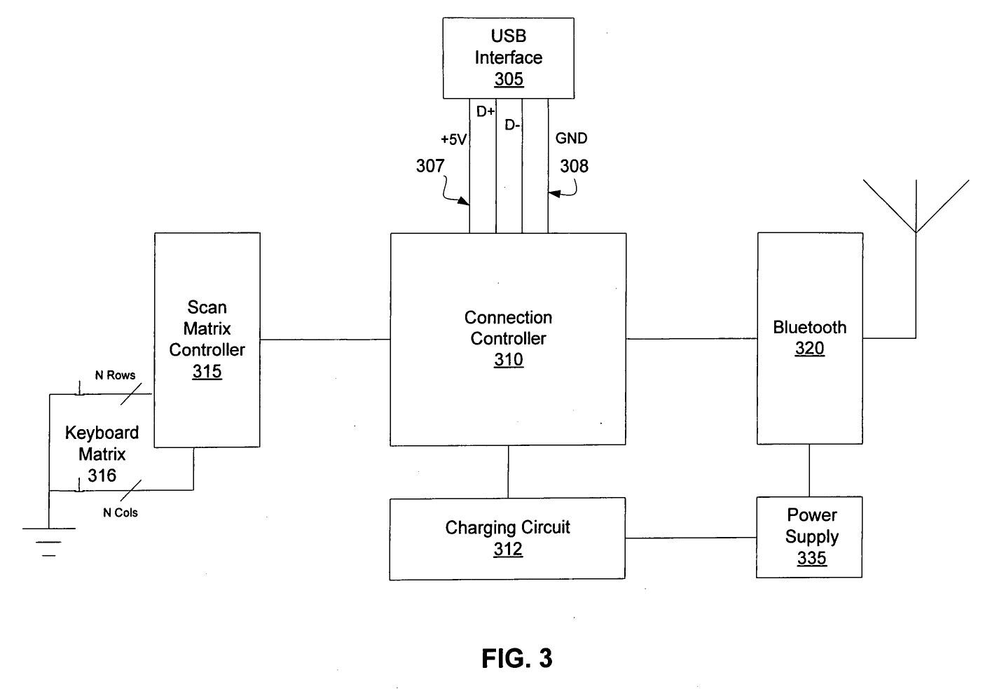

FIG. 3 is an example block diagram that illustrates a USB interface, in accordance with one embodiment. For one embodiment, the keyboard 105 may use power available from the display housing 103. The power may be provided through a power signal via the keyboard connection 195 when using a wired interface. For example, when the wired interface is a USB interface 305, the power signal is available via a power pin 307 of the USB interface 305. The voltage of the power signal 307 may be at 5 Volts. The USB interface 305 may also include a ground signal 308 and USB data signal+(D+) and USB data signal−(D−).

Connection Controller

For one embodiment, the keyboard 105 may include a connection controller 310, as illustrated in FIG. 3. The connection controller 310 may perform various functions including interfacing with the scan matrix controller 315 to receive keyboard data. The scan matrix controller 315 scans the keyboard matrix 316 which may include a number of select lines set to low or high based keyboard rows and columns, etc. Operations of the scan matrix controller 315 are known to one skilled in the art.

For one embodiment, the connection controller 310 may also detect the type of connection between the keyboard 105 and the display housing 103. When the connection controller 310 detects that the keyboard 105 is switching between a wireless connection and a wired connection (e.g., between a Bluetooth connection and a USB connection), the connection controller 310 may perform actions necessary to accommodate the switch. Such actions may include, for example, disabling or removing input to the Bluetooth radio 320, converting from sending keyboard data via the Bluetooth radio 320 to sending the keyboard data via the USB interface 305. The connection controller 310 may be implemented in hardware, software, or a combination of both.

Keyboard with Own DC Power Supply

For one embodiment, the keyboard 105 may include a DC power supply 335. The power supply 335 may be rechargeable. The power supply 335 may enable the keyboard 105 to communicate wirelessly with the display housing 103 via the Bluetooth radio 320. This may be necessary when the base housing 104 is detached from the display housing 103 for an extended period of time.

Charging Circuit

For one embodiment, the keyboard 105 may include a charging circuit 312, as illustrated in FIG. 3. The charging circuit 312 may be used to charge the power supply 335. For one embodiment, the charging circuit 312 may use the power signal 307 from the USB interface 305 to charge the power supply 335. In some situations, it may be necessary to convert the voltage of the power signal 305 to be compatible with the charge voltage of the power supply 335. For example, the voltage of the power signal 307 in the USB interface 305 may be 5 Volts and the charge voltage of the power supply 335 (e.g., Li-on battery) may be 4.2 Volts. A voltage regulator may also be included as part of the charging circuit.

Connection Switching and Charging Process

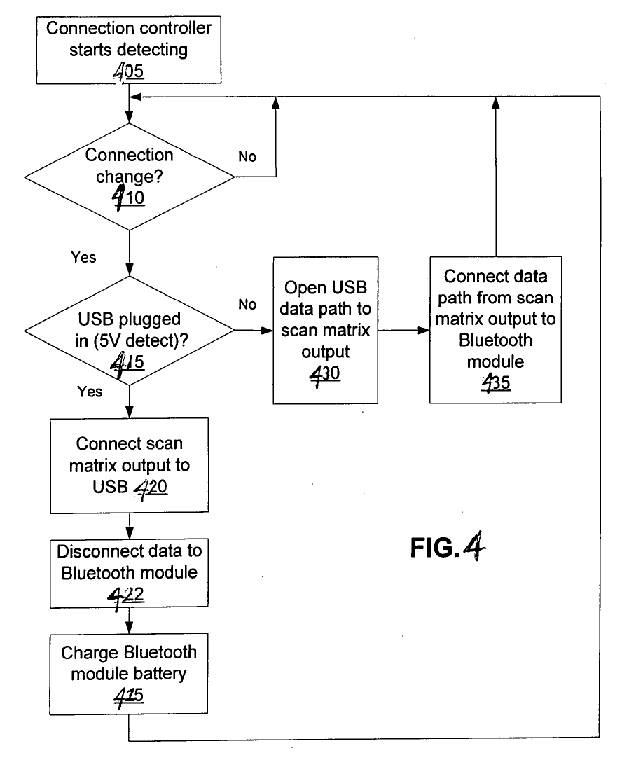

FIG. 4 is a flow diagram illustrating one example of a process that may be performed by the connection controller, in accordance with one embodiment. The process in FIG. 4 starts at block 405 and may correlate to the diagram illustrated in FIG. 3.

At block 410, a test is performed to determine whether a change in the connection of the keyboard 105 is detected. If there is no change, the process returns to block 410 to continue the test. When a change is detected, the process flows from block 410 to block 415.

At block 415, a test is performed to determine whether the change is to a wired connection such as, for example, a USB connection using a USB interface. When the connection is the USB connection, the process flows to block 420, where the connection controller 310 may connect the scan matrix output to the USB interface. At block 422, the connection controller 310 may disconnect the scan matrix output from the wireless interface such as, for example, the Bluetooth interface. At block 425, the connection controller 310 may activate the charging circuit 312 to charge the power supply 335 associated with the Bluetooth interface 320. The process then continues at block 410 to test for another connection change.

From block 415, when there is no wired or USB plugging detected, this may mean that the keyboard connection is changing from a wired interface (e.g., USB interface) to a wireless interface (e.g., Bluetooth interface). The process flows from block 415 to block 430, where the connection controller 310 may disconnect the scan matrix output from the USB interface 305. At block 435, the connection controller 310 may connect the scan matrix output to the Bluetooth interface. Communications from the keyboard 105 to the base housing 103 may continue using the wireless connection. The process then continues at block 410 to test for another connection change.

Although the present invention have been described with reference to specific exemplary embodiments, it will be evident that various modifications and changes may be made to these embodiments without departing from the broader spirit and scope of the invention as set forth in the claims. Accordingly, the specification and drawings are to be regarded in an illustrative rather than a restrictive sense.

What is claimed is:

1. An apparatus, comprising:
a rechargeable power supply;
a wireless interface coupled to the rechargeable power supply and to be used for a wireless connection; and
a wired interface coupled to the rechargeable power supply and to be used for a wired connection, wherein the wired interface is to include a power signal to be used for charging the rechargeable power supply.

2. The apparatus of claim 1, wherein the rechargeable power supply is charged when a wired connection is established.

3. The apparatus of claim 2, wherein the wireless or wired connection is used to communicate with a processor.

4. The apparatus of claim 3, further comprising a charging circuit to charge the rechargeable power supply, the charging circuit coupled to the wired interface.

5. The apparatus of claim 4, wherein the wired interface is a Universal Serial Bus (USB) interface.

6. The apparatus of claim 4, wherein the wireless interface is an infrared (IR) interface.

7. The apparatus of claim 4, wherein the wireless interface is a Bluetooth interface.

8. The apparatus of claim 4, wherein the rechargeable power supply is a battery, and wherein the wired and the wireless interfaces are adapted for an input device.

9. The apparatus of claim 8, wherein the input device is a keyboard or a mouse.

10. A system, comprising:
a housing including a processor; and
an input device detachably connectable to the housing, the input device including a wireless interface and a rechargeable power supply that is to enable the input device to communicate with the processor when the input device is detached from the housing, the input device further including a wired interface that is to enable the input device to communicate with the processor when the input device is attached to the housing, wherein the rechargeable power supply is to be charged using a power signal available in the wired interface.

11. The system of claim 10, wherein the wireless interface is adapted to enable communications using infrared (IR) signals.

12. The system of claim 10, wherein the wireless interface is adapted to enable communications using Bluetooth signals.

13. The system of claim 10, wherein the wired interface is a Universal Serial Bus (USB) interface.

14. The system of claim 10, further comprising:
a controller coupled to the rechargeable power supply, wherein the controller is to detect the input device switching its communications with the processor between the wireless interface and the wired interface.

15. The system of claim 14, wherein the controller is to activate charging the rechargeable power supply when the input device is switched to the wired interface.

16. The system of claim 10, wherein then rechargeable power supply is used when the input device is switched to the wireless interface.

17. A system, comprising:
a processor;
a detachable device coupled to the processor, the detachable device is configurable to communicate with the processor using a wired interface or a wireless interface, the detachable device including a rechargeable power supply; and
a controller coupled to the wired interface and the wireless interface, the controller is to cause the rechargeable power supply to be charged when the wired interface is used.

18. The system of claim 17, wherein the detachable device includes a charging circuit coupled to the controller.

19. The system of claim 18, wherein the controller causes the rechargeable power supply to be charged using the charging circuit and a power signal associated with the wired interface.

20. The system of claim 19, wherein the wired interface is a Universal Serial Bus (USB) interface and the wireless interface is a Bluetooth interface.

21. A method, comprising:
receiving an indication that charge associated with a power supply of a device is low, the power supply used to enable wireless communication using a wireless interface;
switching from the wireless communication to a wired communication using a wired interface, the wireless communication and the wired communication are to be used to communicate with a processor; and
charging the power supply using a power signal associated with the wired interface.

22. The method of claim 21, wherein the wired interface is a Universal Serial Bus (USB) interface, and the wireless interface is a Bluetooth interface.

23. The method of claim 21, wherein the device is a keyboard or a mouse.

24. A method, comprising:
receiving an indication that a connection change is detected, the connection change associated with a wireless connection or a wired connection, wherein the wireless connection is supported using a rechargeable power supply; and
when the connection change is for a wired connection, disabling the wireless connection and charging the rechargeable power supply using a power signal available via the wired connection;

25. The method of claim 21, wherein the wireless interface is a radio link interface.

26. The method of claim 25, wherein the radio link interface is a Bluetooth interface.

27. The method of claim 25, wherein the wired interface is a Universal Serial Bus (USB) interface.
